(19) United States
(12) Patent Application Publication
(10) Pub. No.: US 2025/0266654 A1
(43) Pub. Date: Aug. 21, 2025

(54) GAS LASER DEVICE AND ELECTRONIC DEVICE MANUFACTURING METHOD

(71) Applicant: Gigaphoton Inc., Tochigi (JP)

(72) Inventor: Hitoshi OHGA, Oyama-shi (JP)

(73) Assignee: Gigaphoton Inc., Tochigi (JP)

(21) Appl. No.: 19/009,341

(22) Filed: Jan. 3, 2025

(30) Foreign Application Priority Data
Feb. 16, 2024 (JP) 2024-021951

(51) Int. Cl. H01S 3/036; G03F 7/00; H01S 3/038

(52) U.S. Cl. CPC H01S 3/036; G03F 7/70025; H01S 3/0384; H01S 3/0385

(57) ABSTRACT

A gas laser device is for discharging and exciting a laser gas passing through a discharge space between first and second discharge electrodes and includes a plate supporting the first discharge electrode, a guide member arranged on the plate and guiding the laser gas to the discharge space, a dielectric pipe arranged between the guide member and the first discharge electrode, a first path including the guide member and causing a part of the laser gas to flow therein as a branched flow, a second path including the dielectric pipe and the plate and causing the branched flow flowing out from the first path to flow therethrough, and a third path including the dielectric pipe and the first discharge electrode and guiding the branched flow flowing out from the second path to upstream of the laser gas with respect to the discharge space.

### CROSS-REFERENCE TO RELATED APPLICATIONS

The present application claims the benefit of Japanese Patent Application No. 2024-021951, filed on Feb. 16, 2024, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent No. 2714357
Patent Document 2: U.S. Pat. No. 6,529,538

### SUMMARY

A gas laser device, according to an aspect of the present disclosure, for discharging and exciting a laser gas passing through a discharge space between a first discharge electrode and a second discharge electrode includes a plate supporting the first discharge electrode; a guide member arranged on the plate and configured to guide the laser gas to the discharge space; a dielectric pipe arranged between the guide member and the first discharge electrode as being spaced apart from each of the plate and the first discharge electrode; a first path configured as including the guide member, and causing a part of the laser gas to flow therein as a branched flow; a second path configured as including the dielectric pipe and the plate, and causing the branched flow flowing out from the first path to flow therethrough; and a third path configured as including the dielectric pipe and the first discharge electrode, and guiding the branched flow flowing out from the second path to upstream of the laser gas with respect to the discharge space.

An electronic device manufacturing method according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device is a gas laser device for discharging and exciting a laser gas passing through a discharge space between a first discharge electrode and a second discharge electrode and includes a plate supporting the first discharge electrode; a guide member arranged on the plate and configured to guide the laser gas to the discharge space; a dielectric pipe arranged between the guide member and the first discharge electrode as being spaced apart from each of the plate and the first discharge electrode; a first path configured as including the guide member, and causing a part of the laser gas to flow therein as a branched flow; a second path configured as including the dielectric pipe and the plate, and causing the branched flow flowing out from the first path to flow therethrough; and a third path configured as including the dielectric pipe and the first discharge electrode, and guiding the branched flow flowing out from the second path to upstream of the laser gas with respect to the discharge space.

### BRIEF DESCRIPTION OF THE DRAWINGS

Embodiments of the present disclosure will be described below merely as examples with reference to the accompanying drawings.

FIG. 1 is a side view schematically showing the configuration of a gas laser device according to a comparative example.

FIG. 2 is a sectional view schematically showing the configuration of the gas laser device according to the comparative example.

FIG. 3 is a sectional view showing in detail the configuration of the vicinity of a main electrode in a laser chamber.

FIG. 4 is a diagram showing an example of an ideal flow velocity distribution of a laser gas passing through a discharge space.

FIG. 5 is a timing chart showing operation of the gas laser device.

FIG. 6 is a view showing an example of a simulation result of a flow of the laser gas.

FIG. 7 is a diagram showing an example of the flow velocity distribution of the laser gas passing through a discharge space in a case in which missing occurs.

FIG. 8 is a sectional view showing in detail the configuration of the vicinity of the main electrode in the laser chamber according to a first embodiment.

FIG. 9 is an enlarged view of the vicinity of a dielectric pipe.

FIG. 10 is a plan view of a part including an anode electrode and the dielectric pipe viewed from the discharge space.

FIG. 11 is a view showing an example of a simulation result of the flow of the laser gas in the first embodiment.

FIG. 12 is a diagram showing an example of the flow velocity distribution of the laser gas passing through the discharge space in the first embodiment.

FIG. 13 is a timing chart showing operation of the gas laser device according to the first embodiment.

FIG. 14 is a view showing in detail the configuration of the vicinity of the main electrode in the laser chamber according to a second embodiment.

FIG. 15 is a plan view of the part including the anode electrode and the dielectric pipe viewed from the discharge space.

FIG. 16 is a view showing an example of a simulation result of the flow of the laser gas in the second embodiment.

FIG. 17 is a diagram schematically showing a configuration example of an exposure apparatus.

### DESCRIPTION OF EMBODIMENTS

### Contents

1. Comparative example
   1.1 Configuration
   1.2 Operation
   1.3 Problem
2. First Embodiment
   2.1 Configuration
   2.2 Operation
   2.3 Effect
3. Second Embodiment
   3.1 Configuration
   3.2 Operation
   3.3 Effect
4. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Configuration

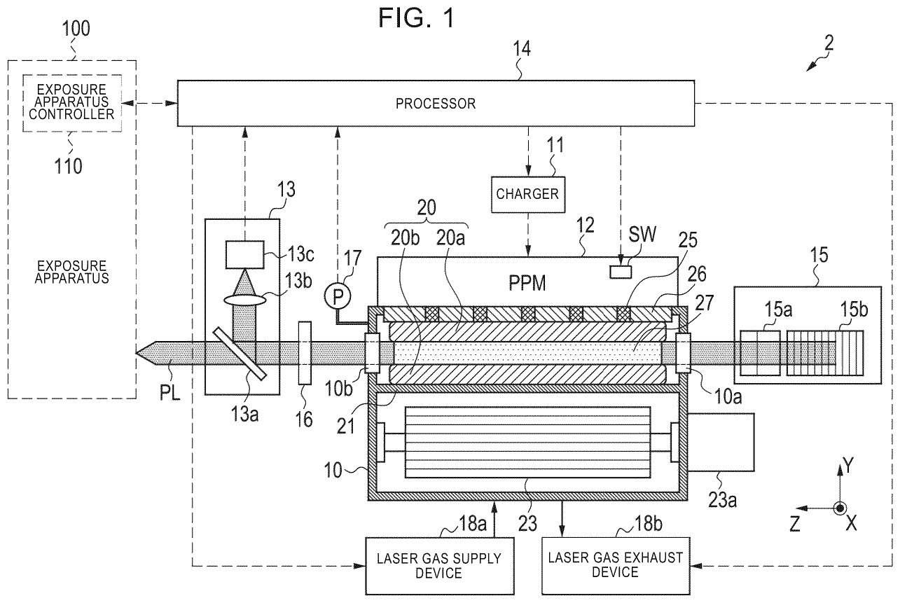

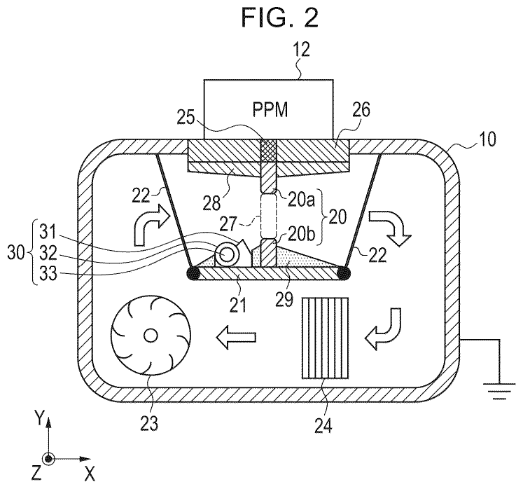

The configuration of a gas laser device 2 according to the comparative example will be described using FIGS. 1 and 2. FIG. 1 schematically shows the configuration of the gas laser device 2. FIG. 2 is a sectional view of the gas laser device 2 shown in FIG. 1 viewed from a Z direction. The gas laser device 2 is a discharge-excitation-type gas laser device that discharges and excites a laser gas, and is, for example, an excimer laser device.

In FIG. 1, the travel direction of pulse laser light PL output from the gas laser device 2 is defined as the Z direction. A discharge direction to be described later is defined as a Y direction. A direction orthogonal to the Z direction and the Y direction is defined as an X direction. Here, the pulse laser light PL is an example of the “laser light” according to the technology of the present disclosure.

In FIG. 1, the gas laser device 2 includes a laser chamber 10, a charger 11, a pulse power module (PPM) 12, a pulse energy measurement unit 13, a processor 14, a pressure sensor 17, and a laser resonator. The laser resonator is configured of a line narrowing module 15 and an output coupling mirror 16.

The laser chamber 10 is, for example, a metal container made of aluminum metal plated with nickel on the surface thereof. As shown in FIGS. 1 and 2, a main electrode 20, a ground plate 21, wirings 22, a fan 23, a heat exchanger 24, an insulating guide 28, a conductive guide 29, and a preionization electrode 30 are provided in the laser chamber 10. The preionization electrode 30 includes a preionization outer electrode 31, a dielectric pipe 32, and a preionization inner electrode 33.

A laser gas containing fluorine as a laser medium is enclosed in the laser chamber 10. The laser gas includes, for example, argon, krypton, xenon, or the like as a rare gas, neon, helium, or the like as a buffer gas, and fluorine, chlorine, or the like as a halogen gas.

Further, an opening is formed in the laser chamber 10. An electrically insulating plate 26 in which a feedthrough 25 is embedded is attached to the laser chamber 10 via an O-ring (not shown) so as to close the opening. The PPM 12 is arranged on the electrically insulating plate 26. The laser chamber 10 is grounded.

The PPM 12 includes a charging capacitor (not shown) and is connected to the main electrode 20 via the feedthrough 25. The PPM 12 includes a switch SW for causing discharge to occur at the main electrode 20. The charger 11 is connected to the charging capacitor of the PPM 12. Hereinafter, the discharge occurring at the main electrode 20 is referred to as main discharge.

The main electrode 20 includes a cathode electrode 20a and an anode electrode 20b. The cathode electrode 20a and the anode electrode 20b are arranged in the laser chamber 10 so that discharge surfaces of the both face each other. The space between the discharge surface of the cathode electrode 20a and the discharge surface of the anode electrode 20b is referred to as a discharge space 27. The cathode electrode 20a is supported by the electrically insulating plate 26 on a surface opposite to the discharge surface thereof, and is connected to the feedthrough 25. The anode electrode 20b is supported by the ground plate 21 on a surface opposite to the discharge surface thereof. The anode electrode 20b is an example of the “first discharge electrode” according to the technology of the present disclosure. The cathode electrode 20a is an example of the “second discharge electrode” according to the technology of the present disclosure. The ground plate 21 is an example of the “plate” according to the technology of the present disclosure.

The ground plate 21 is connected to the laser chamber 10 via the wirings 22. The laser chamber 10 is grounded. Therefore, the ground plate 21 is grounded via the wirings 22. An end part of the ground plate 21 in the Z direction is fixed to the laser chamber 10.

The fan 23 is a cross flow fan for circulating the laser gas in the laser chamber 10, and is arranged on the opposite side of the discharge space 27 with respect to the ground plate 21. A motor 23a for rotationally driving the fan 23 is connected to the laser chamber 10.

The laser gas blown out from the fan 23 flows into the discharge space 27. The flow direction of the laser gas flowing into the discharge space 27 is substantially parallel to the X direction. The laser gas flowing out 27 from the discharge space 27 can be sucked into the fan 23 via the heat exchanger 24. The heat exchanger 24 changes the temperature of the laser gas by performing heat exchange between a refrigerant supplied to the inside of the heat exchanger 24 and the laser gas.

The insulating guide 28 is arranged on a surface of the electrically insulating plate 26 facing the discharge space 27 so as to sandwich the cathode electrode 20a. The insulating guide 28 is formed in a shape to guide the flow of the laser gas so that the laser gas from the fan 23 efficiently flows between the cathode electrode 20a and the anode electrode 20b. The insulating guide 28 and the electrically insulating plate 26 are made of, for example, ceramics such as alumina (Al₂O₃) having low reactivity with the fluorine gas.

The conductive guide 29 is arranged on a surface of the ground plate 21 facing the discharge space 27 so as to sandwich the anode electrode 20b. Similarly to the insulating guide 28, the conductive guide 29 is formed in a shape to guide the flow of the laser gas so that the laser gas from the fan 23 efficiently flows between the cathode electrode 20a and the anode electrode 20b. The conductive guide 29 is made of, for example, a porous nickel metal having low reactivity with the fluorine gas.

A laser gas supply device 18a and a laser gas exhaust device 18b are connected to the laser chamber 10. The laser gas supply device 18a includes a valve and a flow rate control valve, and is connected to a gas cylinder accommodating the laser gas. The laser gas exhaust device 18b includes a valve and an exhaust pump.

At an end part of the laser chamber 10, each of the windows 10a, 10b for outputting light generated in the laser chamber 10 to the outside is provided. The laser chamber 10 is arranged such that the optical path of the optical resonator passes through the discharge space 27 and the windows 10a, 10b.

The line narrowing module 15 includes a prism 15a and a grating 15b. The prism 15a transmits the light output from the laser chamber 10 through the window 10a toward the grating 15b while expanding the beam width of the light.

The grating 15b is arranged in the Littrow arrangement in which the incident angle and the diffraction angle are the same. The grating 15b is a wavelength selection element that selectively extracts light having a wavelength near a particular wavelength in accordance with the diffraction angle. The spectral width of the light returning from the grating 15b to the laser chamber 10 via the prism 15a is line-narrowed.

The output coupling mirror 16 transmits a part of the light output from the laser chamber 10 through the window 10b, and reflects the other part back into the laser chamber 10. The surface of the output coupling mirror 16 is coated with a partial reflection film.

Light output from the laser chamber 10 reciprocates between the line narrowing module 15 and the output coupling mirror 16, and is amplified each time the light passes through the discharge space 27. A part of the amplified light is output as the pulse laser light PL via the output coupling mirror 16.

The pulse energy measurement unit 13 is arranged on the optical path of the pulse laser light PL output via the output coupling mirror 16. The pulse energy measurement unit 13 includes a beam splitter 13a, a light concentrating optical system 13b, and an optical sensor 13c.

The beam splitter 13a transmits the pulse laser light PL with a high transmittance and reflects a part of the pulse laser light PL toward the light concentrating optical system 13b. The light concentrating optical system 13b concentrates the light reflected by the beam splitter 13a on a light receiving surface of the optical sensor 13c. The optical sensor 13c measures the pulse energy of the light concentrated on the light receiving surface, and outputs the measurement value to the processor 14.

The pressure sensor 17 detects the gas pressure in the laser chamber 10, and outputs the detection value to the processor 14. The processor 14 determines the gas pressure of the laser gas in the laser chamber 10 based on the detection value of the gas pressure and the charge voltage of the charger 11.

The charger 11 is a high voltage power source that supplies the charge voltage to the charging capacitor included in the PPM 12. The switch SW of the PPM 12 is controlled by the processor 14. When the switch SW is turned ON from OFF, the PPM 12 generates a high voltage pulse from the electric energy held in the charging capacitor and applies the high voltage pulse to the main electrode 20.

The processor 14 is a processing device that transmits and receives various signals to and from an exposure apparatus controller 110 provided in an exposure apparatus 100. For example, the exposure apparatus controller 110 transmits, to the processor 14, a target pulse energy of the pulse laser light PL to be output to the exposure apparatus 100, an oscillation trigger signal, and the like.

The processor 14 generally controls operation of each component of the gas laser device 2 based on various signals transmitted from the exposure apparatus controller 110, the measurement value of the pulse energy, the detection value of the gas pressure, and the like.

The processor 14 functions as a controller of the gas laser device 2. For example, the processor 14 is a processing device including a storage device in which a control program is stored and a central processing unit (CPU) that executes the control program. The processor 14 is specifically configured or programmed to perform various processes included in the present disclosure. The storage device is a non-transitory computer-readable storage medium, and includes, for example, a memory that is a main storage device and a storage that is an auxiliary storage device. Here, the storage device may be a semiconductor memory, a hard disk drive (HDD) device, a solid state drive (SSD) device, or a combination thereof.

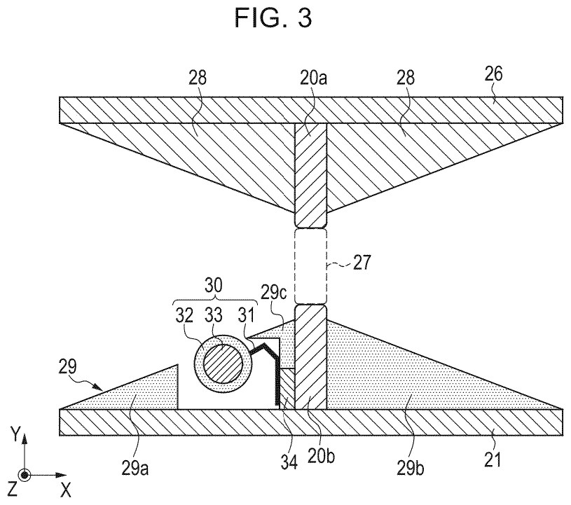

FIG. 3 shows in detail the configuration of the vicinity of the main electrode 20 in the laser chamber 10. In the following description, the upstream side refers to a side, with respect to the discharge space 27, from which the laser gas flows into the discharge space 27. The downstream side refers to a side, with respect to the discharge space 27, to which the laser gas flows out from the discharge space 27.

The preionization outer electrode 31 is arranged between the anode electrode 20b and the dielectric pipe 32, and is held in contact with a side surface of a holding member 34 made of metal. The holding member 34 is fixed to an upstream side surface of the anode electrode 20b. The preionization inner electrode 33 is arranged in the dielectric pipe 32, and the preionization outer electrode 31 is in contact with the outside of the dielectric pipe 32.

The insulating guide 28 is arranged so as to cover the upstream and downstream side surfaces of the cathode electrode 20a. The surface of the insulating guide 28 is inclined so as to be closer to the electrically insulating plate 26 as the distance from the cathode electrode 20a increases.

The conductive guide 29 includes a first guide member 29a, a second guide member 29b, and a third guide member 29c. The first guide member 29a and the third guide member 29c are arranged upstream of the anode electrode 20b. The second guide member 29b is arranged downstream of the anode electrode 20b. The first guide member 29a is an example of the “guide member” according to the technology of the present disclosure.

The first guide member 29a is arranged on the ground plate 21 so as to guide the laser gas to the discharge space 27. The dielectric pipe 32 is arranged between the first guide member 29a and the anode electrode 20b so as to be spaced apart from each of the ground plate 21 and the anode electrode 20b. The second guide member 29b is arranged on the ground plate 21 downstream of the anode electrode 20b so as to cover the downstream side surface of the anode electrode 20b.

The third guide member 29c is arranged between the dielectric pipe 32 and the anode electrode 20b so as to cover the upstream side surface of the anode electrode 20b and to guide the laser gas to the discharge space 27. The third guide member 29c is close to the dielectric pipe 32.

The surface of the conductive guide 29 is inclined as a whole so as to be closer to the ground plate 21 as the distance from the anode electrode 20b increases.

Each of the upstream and downstream side surfaces of the cathode electrode 20a in the vicinity of the discharge surface thereof are not covered with the insulating guide 28, and the cathode electrode 20a protrudes from the surface of the insulating guide 28 toward the anode electrode 20b. Thus, the discharge surface of the cathode electrode 20a is spaced apart from the surface of the insulating guide 28.

Each of the upstream and downstream side surfaces of the anode electrode 20b in the vicinity of the discharge surface thereof are not covered with the conductive guide 29, and the anode electrode 20b protrudes from the surface of the conductive guide 29 toward the cathode electrode 20a. Thus, the discharge surface of the anode electrode 20b is spaced apart from the surface of the conductive guide 29.

### 1.2 Operation

Next, operation of the gas laser device 2 according to the comparative example will be described. First, the processor 14 controls the laser gas supply device 18a to supply the laser gas into the laser chamber 10, and drives the motor 23a to rotate the fan 23. As a result, as indicated by arrows in FIG. 2, the laser gas filled in the laser chamber 10 circulates.

The processor 14 receives the target pulse energy and the oscillation trigger signal from the exposure apparatus controller 110. Here, the oscillation trigger signal is a signal for instructing the gas laser device 2 to output one pulse of the pulse laser light PL.

The processor 14 sets the charge voltage corresponding to the target pulse energy in the charger 11. The processor 14 operates the switch SW of the PPM 12 in synchronization with the oscillation trigger signal.

When the switch SW of the PPM 12 is turned ON from OFF, a voltage is applied to each between the preionization inner electrode 33 and the preionization outer electrode 31 of the preionization electrode 30 and between the cathode electrode 20a and the anode electrode 20b. As a result, corona discharge occurs at the preionization electrode 30, and ultraviolet (UV) light is generated. When the laser gas in the discharge space 27 is irradiated with the UV light, the laser gas is preionized.

Thereafter, when the voltage between the cathode electrode 20a and the anode electrode 20b reaches a breakdown voltage, main discharge occurs in the discharge space 27. When the discharge direction of the main discharge is defined as a direction in which electrons flow, the discharge direction is the direction from the cathode electrode 20a toward the anode electrode 20b. When the main discharge occurs, the laser gas in the discharge space 27 is excited to emit light.

The light emitted from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser light PL.

A part of the pulse laser light PL output from the output coupling mirror 16 enters the pulse energy measurement unit 13. The pulse energy measurement unit 13 measures the pulse energy of the entering pulse laser light PL, and outputs the measurement value to the processor 14.

The processor 14 calculates a difference ΔE between the measurement value of the pulse energy and the target pulse energy. The processor 14 performs feedback control on the charge voltage based on the difference ΔE so that the measurement value of the pulse energy becomes the target pulse energy.

When the charge voltage is higher than a maximum value of an allowable range, the processor 14 controls the laser gas supply device 18a to supply the laser gas into the laser chamber 10 until a predetermined pressure is reached. Further, when the charge voltage is lower than a minimum value of the allowable range, the processor 14 controls the laser gas exhaust device 18b to exhaust the laser gas from the laser chamber 10 until a predetermined pressure is reached.

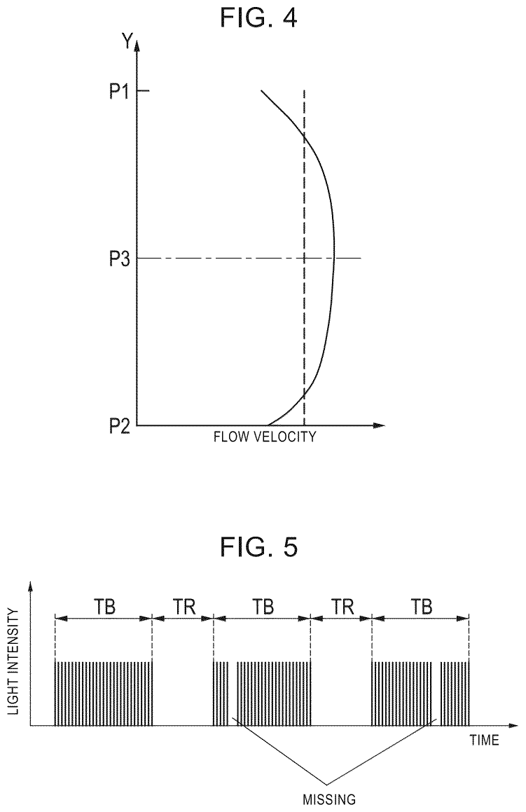

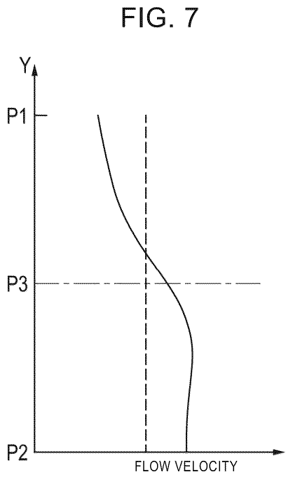

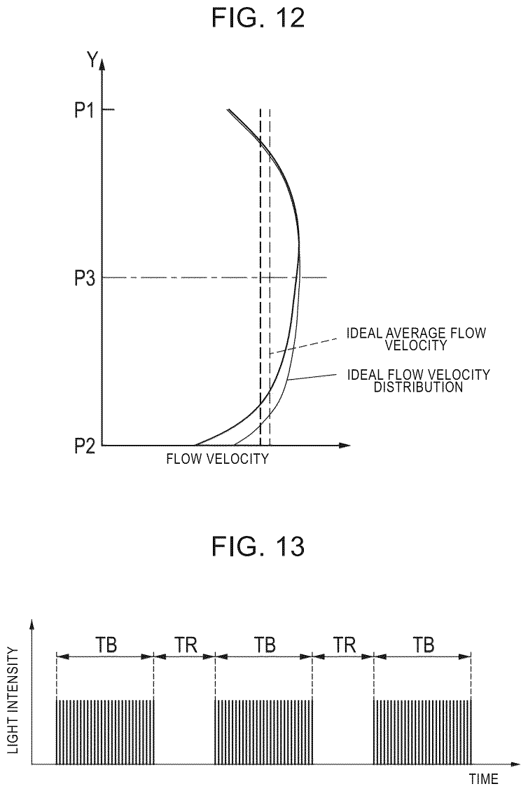

FIG. 4 shows an example of an ideal flow velocity distribution of the laser gas passing through the discharge space 27. In FIG. 4, P1 represents the position of the discharge surface of the cathode electrode 20a in the Y direction, and P2 represents the position of the discharge surface of the anode electrode 20b in the Y direction. Further, P3 represents the center position of the discharge space 27 in the Y direction. A solid line represents the flow velocity distribution of the laser gas, and a broken line represents an average flow velocity calculated from the flow velocity distribution of the laser gas. The same applies to FIGS. 7 and 12 described later.

A discharge product is generated in the discharge space 27 by the main discharge. Since the discharge product has conductivity, if the discharge product stays in the discharge space 27, arc discharge caused by the discharge product may occur. However, the laser gas is rectified by the surface of the insulating guide 28 and the surface of the conductive guide 29, and passes through the discharge space 27 ideally with a flow velocity distribution as shown in FIG. 4. The discharge product generated in the discharge space 27 moves downstream and is removed by the laser gas, so that occurrence of the arc discharge caused by the discharge product is suppressed.

### 1.3 Problem

FIG. 5 is a timing chart showing an example of operation of the gas laser device 2. When the exposure apparatus 100 exposes a semiconductor wafer, exposure is performed by a so-called “burst output” in which the pulse laser light PL is output from the gas laser device 2 at a predetermined repetition frequency. Here, for example, in a period in which the semiconductor wafer is moved, the semiconductor wafer is exchanged, a mask is exchanged, or the like in the exposure apparatus 100, the exposure with the pulse laser light PL is paused. That is, in the exposure using the gas laser device 2, a burst output period TB in which the burst output is performed and a burst pause period TR in which the burst output is paused are repeated.

When the above-described arc discharge occurs during the burst output period TB, the laser gas is not sufficiently excited during the arc discharge, so that a so-called “missing” in which the pulse laser light PL is not output occurs. In the gas laser device 2 according to the comparative example, when the discharge product in the discharge space 27 is removed by the flow of the laser gas as described above, it is considered that missing is suppressed. However, as shown in FIG. 5, the applicant of the present invention has confirmed that there is a case in which missing during the burst output period TB occurs in the gas laser device 2 according to the comparative embodiment.

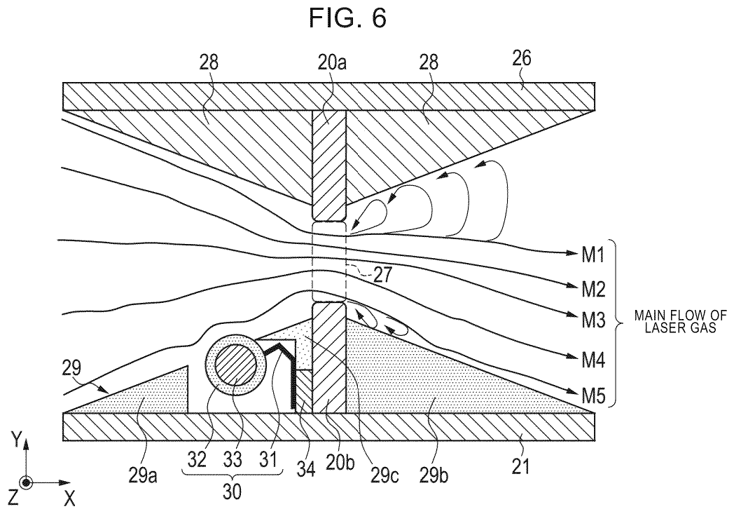

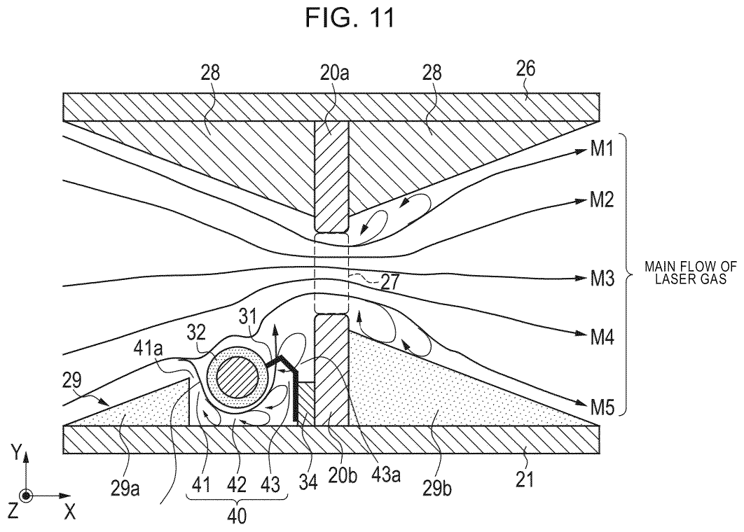

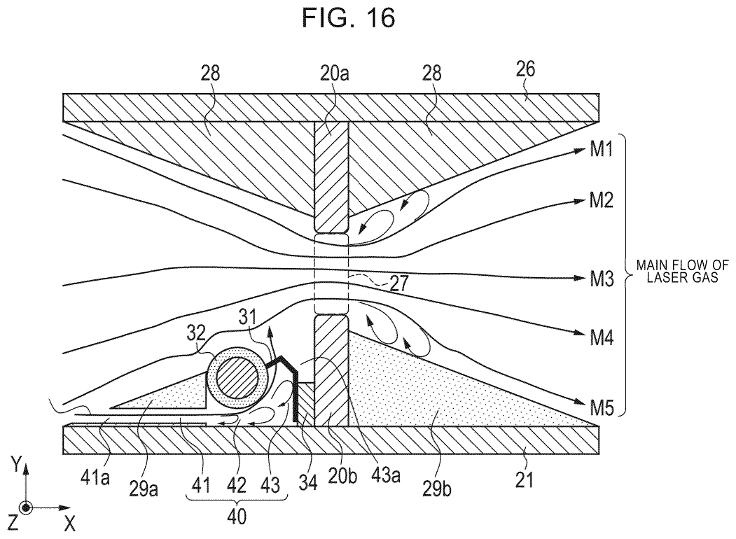

Therefore, the applicant performed a simulation on the flow of the laser gas to presume the cause of occurrence of missing. FIG. 6 shows an example of a simulation result of the flow of the laser gas. The flow of the laser gas includes a “main flow” that is a laminar flow that travels along the surfaces of the insulating guide 28 and the conductive guide 29 at high speed in the X direction without being separated at the discharge surfaces of the cathode electrode 20a and the anode electrode 20b. The laminar flow refers to a state in which a fluid flows regularly in a certain direction. In FIG. 6, M1 to M5 represent a plurality of components included in the main flow. The same applies to FIGS. 11 and 16 described later.

In addition to the main flow, the flow of the laser gas includes “stagnation” occurring downstream of each of the cathode electrode 20a and the anode electrode 20b. Stagnation includes a turbulent flow occurring by separation of the laser gas at the discharge surfaces of the cathode electrode 20a and the anode electrode 20b, and the laser gas separated from the main flow by the turbulent flow. Further, stagnation includes the laser gas that travels along the surfaces of the insulating guide 28 and the conductive guide 29 at low speed in the X direction and stays between the main flow and the surfaces. The distribution of stagnation is presumed to be the cause of the occurrence of missing.

Stagnation stays while including a flow in a direction opposite to the direction of the main flow, and causes a part of the main flow after passing through the discharge space 27 to transition to stagnation. Therefore, it is presumed that stagnation is a factor that lowers the flow velocity by giving a flow path resistance to the main flow. Hereinafter, stagnation occurring in a cathode-side space between the surface of the insulating guide 28 and the main flow is referred to as “cathode-side stagnation.” Further, stagnation occurring in an anode-side space between the surface of the conductive guide 29 and the main flow is referred to as “anode-side stagnation.”

It is presumed that the laser gas having passed through the discharge space 27 flows in a state of being biased toward the second guide member 29b while receiving a force in the −Y direction by a suction action due to rotation of the fan 23. Therefore, it is presumed that the cathode-side stagnation and the anode-side stagnation are asymmetric.

Specifically, the cathode-side stagnation occurring at the discharge surface of the cathode electrode 20a is successively fed into the cathode-side space. The cathode-side stagnation becomes enlarged while taking in a part of the main flow. As a result, the main flow component M1 travels while being decelerated by receiving a large flow path resistance from the cathode-side stagnation without re-adhering to the insulating guide 28. Further, it is presumed that the deceleration of the main flow component M1 causes a chain deceleration of the main flow components M2 to M4. Re-adhering refers to a phenomenon in which a fluid flowing along a wall surface separates from the wall surface and then flows again along the wall surface as a laminar flow.

The anode-side stagnation occurring at the anode electrode 20b is successively fed into the anode-side space as well, but since the laser gas flows while receiving a force in the −Y direction, the occurring anode-side stagnation immediately re-adheres, so that enlargement is suppressed. Owing to that enlargement of the anode-side stagnation is suppressed, the main flow component M5 re-adheres to the conductive guide 29, and the flow path resistance is reduced. As a result, since the flow velocity of the main flow component M5 increases, it is presumed that the main flow having passed through the discharge space 27 flows in a state of being biased toward the conductive guide 29 as a whole.

FIG. 7 shows an example of the flow velocity distribution of the laser gas passing through the discharge space 27 in the case in which missing occurs. When missing occurs, there occurs a decrease in the flow velocity in the vicinity of the position P1 of the discharge surface of the cathode electrode 20a and a decrease in the average flow velocity due to the decrease. It is presumed that, as a result, a removing rate of the discharge product decreases and the arc discharge occurs, thereby causing missing.

In order to increase the removing rate of the discharge product, it is conceivable to increase the number of revolutions of the fan 23 to increase the flow rate of the laser gas. However, when the number of revolutions of the fan 23 is increased, various problems arise such as an increase in power consumption, difficulty in controlling the fan 23, unevenness in the flow velocity due to an increase in vibration of the fan 23, and breakage of the fan 23.

Although it is also conceivable to decrease the number of revolutions of the fan 23 to suppress enlargement of the cathode-side stagnation, the removing rate of the discharge product decreases when the number of revolutions of the fan 23 is decreased. Further, in this case, it is not possible to perform burst output operation at a high repetition frequency.

Therefore, an object of the present disclosure is to provide a gas laser device and an electronic device manufacturing method that enable burst output without missing.

### 2. First Embodiment

### 2.1 Configuration

The gas laser device 2 according to a first embodiment of the present disclosure has a configuration similar to that of the gas laser device 2 according to the comparative example except that the configuration in the laser chamber 10 is different.

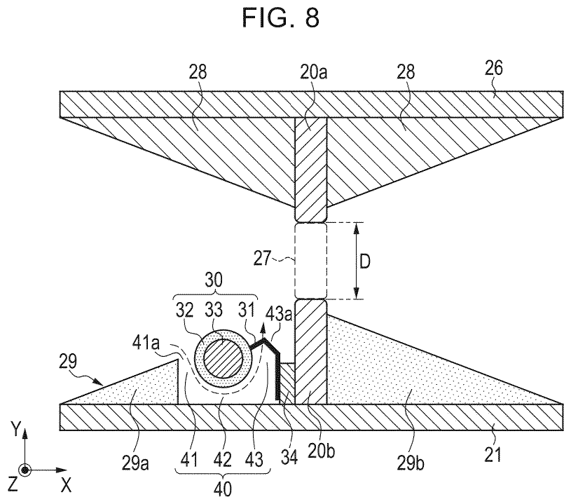

FIG. 8 shows in detail the configuration of the vicinity of the main electrode 20 in the laser chamber 10 according to the first embodiment. The present embodiment differs from the comparative embodiment only in that the third guide member 29c shown in FIG. 6 is not provided. That is, in the present embodiment, the conductive guide 29 includes the first guide member 29a and the second guide member 29b. Accordingly, in the present embodiment, a branched flow path 40 through which a branched flow branched from the main flow of the laser gas flows is formed around the dielectric pipe 32.

The branched flow path 40 includes a first path 41, a second path 42, and a third path 43. The first path 41 is configured including the first guide member 29a, and a part of the laser gas of the main flow flows therein as the branched flow. The second path 42 is configured including the dielectric pipe 32 and the ground plate 21, and the branched flow flowing out of the first path 41 flows therethrough. The third path 43 is configured including the dielectric pipe 32 and the anode electrode 20b, and guides the branched flow flowing out of the second path 42 to upstream of the discharge space 27. In the present embodiment, the first path 41 is configured including the first guide member 29a and the dielectric pipe 32.

Specifically, the first path 41 is a gap between the dielectric pipe 32 and the first guide member 29a. The second path 42 is a gap between the dielectric pipe 32 and the ground plate 21. The third path 43 is a gap between the dielectric pipe 32 and the anode electrode 20b. Here, the holding member 34 and a part of the preionization outer electrode 31 are present in the third path 43.

The first path 41 has, at an end thereof, an inlet port 41a into which a part of the laser gas of the main flow flows. The third path 43 has, at an end thereof, an outlet port 43a through which the branched flow flows out toward the main flow. The branched flow flowing in from the inlet port 41a flows through the branched flow path 40 in the order of the first path 41, the second path 42, and the third path 43, flows out from the outlet port 43a, and merges into the main flow at upstream of the discharge space 27.

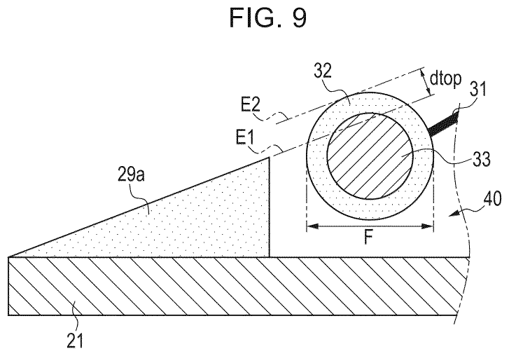

FIG. 9 is an enlarged view of the vicinity of the dielectric pipe 32. The front surface of the first guide member 29a is a plane parallel to the Z direction and non-parallel to the X direction and the Y direction. E1 is an imaginary plane obtained by extending the front surface of the first guide member 29a toward the discharge space 27. E2 is an imaginary plane parallel to the imaginary plane E1 and in contact with the front surface of the dielectric pipe 32. F is an outer diameter of the dielectric pipe 32.

To cause a part of the laser gas of the main flow to flow into the branched flow path 40, it is preferable that the dielectric pipe 32 partially protrudes from the imaginary plane E1 toward the main flow. A protrusion amount dtop of the dielectric pipe 32 is defined by the distance between the imaginary plane E1 and the imaginary plane E2. The protrusion amount dtop and the outer diameter F preferably satisfy the relationship of 0<dtop≤0.5 F.

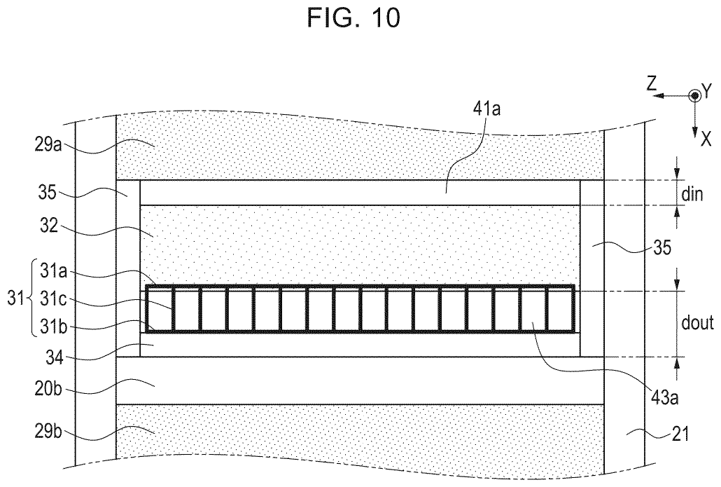

FIG. 10 is a plan view of a part including the anode electrode 20b and the dielectric pipe 32 viewed from the discharge space 27. The discharge surface of the anode electrode 20b is a rectangular extending in the Z direction. The first guide member 29a, the second guide member 29b, the dielectric pipe 32, and the preionization outer electrode 31 are arranged along the longitudinal direction of the discharge surface of the anode electrode 20b.

The dielectric pipe 32 extends in the Z direction, and both ends thereof are held by a pair of holding members 35. The pair of holding members 35 are arranged on the ground plate 21, and form both end faces of the branched flow path 40 in the Z direction. The inlet port 41a and the outlet port 43a are each rectangular extending in the Z direction.

The preionization outer electrode 31 includes a contact portion 31a, a fixed portion 31b, and a plurality of connection portions 31c. The contact portion 31a extends in the Z direction and is in contact with the dielectric pipe 32. The fixed portion 31b extends in the Z direction and is held by the holding member 34. Each of the connection portions 31c extends in the X direction and is connected between the contact portion 31a and the fixed portion 31b. The plurality of connection portions 31c are arranged at equal intervals in the Z direction. The preionization outer electrode 31 is ladder-shaped as a whole, and spaces between two adjacent connection portions 31c are present at the outlet port 43a respectively, and the branched flow of the laser gas passes through the spaces.

When the minimum width of the inlet port 41a in a direction perpendicular to the flowing direction of the branched flow is defined as din and the minimum width of the outlet port 43a in the direction perpendicular to the flowing direction of the branched flow is defined as dout, it is preferable that the relationship of dout≥din is satisfied. Further, when the distance between the discharge surface of the cathode electrode 20a and the discharge surface of the anode electrode 20b is defined as D, it is preferable that the relationship of 0.1D≤din≤0.5D is satisfied. In the present embodiment, the minimum width din is the length of the inlet port 41a in the X direction, and the minimum width dout is the length of the outlet port 43a in the X direction.

### 2.2 Operation

The operation of the gas laser device 2 according to the present embodiment is similar to that of the comparative example except that the effect caused by the formation of the branched flow path 40 is different.

FIG. 11 shows an example of a simulation result of the flow of the laser gas in the first embodiment. As shown in FIG. 11, in the present embodiment, a part of the main flow component M5 is separated and flows into the branched flow path 40 from the inlet port 41a. The branched flow travels through the branched flow path 40 along the surface of the dielectric pipe 32 and reaches the outlet port 43a. Here, it is presumed that the principle of the branched flow occurring and traveling through the branched flow path 40 is due to the Coanda effect.

In the branched flow path 40, stagnation having a flow component opposite to the travel direction of the branched flow occurs on the side surface of the first guide member 29a, the front surface of the ground plate 21, the side surface of the holding member 34, and the side surface of the anode electrode 20b. Hereinafter, stagnation occurring in the branched flow path 40 is referred to as branched flow stagnation.

The branched flow having reached the outlet port 43a passes through the ladder-shaped space of the preionization outer electrode 31 and flows out toward the insulating guide 28 located upstream, that is, toward the +Y direction. The branched flow having flown out merges with the main flow component M5 at a position upstream of the discharge space 27. Thus, the branched flow has kinetic energy that can overcome the branched flow stagnation and merges with the main flow component M5.

The main flow component M5 after the branched flow merges enters the discharge space 27 in a state of being biased toward the cathode electrode 20a than in the comparative example shown in FIG. 6. At this time, the main flow components M1 to M4 also enter the discharge space 27 in a state of being biased toward the cathode electrode 20a by being affected by the main flow component M5 in a chain reaction. Therefore, the main flow enters the discharge space 27 in a state of being biased toward the cathode electrode 20a as a whole as compared with the comparative example.

In summary, according to the present embodiment, first to fourth effects described below can be obtained.

As a first effect, the branched flow having kinetic energy that can change the position of the main flow occurs. Since the branched flow occurring by the Coanda effect travels through the branched flow path 40 along the surface of the dielectric pipe 32, the branched flow flows out from the branched flow path 40 without losing much kinetic energy. This first effect occurs at all positions in the Z direction of the branched flow path 40. As a result, the branched flow having little variation of kinetic energy in the Z direction flows out from the outlet port 43a.

As a second effect, the branched flow oriented toward the +Y direction flows out from the outlet port 43a. Since the dielectric pipe 32 is located upstream of the discharge space 27, the branched flow occurring by the Coanda effect is separated from the dielectric pipe 32 and flows out from the outlet port 43a in the +Y direction. Further, since the dielectric pipe 32 extends in the Z direction, the branched flow flows out in the +Y direction from all positions in the Z direction at the outlet port 43a.

As a third effect, the entire main flow is displaced toward the cathode electrode 20a. Since the branched flow traveling in the +Y direction merges with the main flow entering the discharge space 27 in the +X direction, the entire main flow enters the discharge space 27 while being displaced toward the cathode electrode 20a.

As a fourth effect, the symmetry between the cathode-side stagnation and the anode-side stagnation is improved. Owing to that the entire main flow enters the discharge space 27 while being displaced toward the cathode electrode 20a, re-adhering of the main flow component M1 in the cathode-side space is promoted, and enlargement of the cathode-side stagnation is suppressed. On the other hand, re-adhering of the main flow component M5 is delayed in the anode-side space, so that the anode-side stagnation becomes enlarged. Thus, the symmetry between the cathode-side stagnation and the anode-side stagnation is improved.

FIG. 12 shows an example of the flow velocity distribution of the laser gas passing through the discharge space 27 in the first embodiment. FIG. 12 shows an ideal flow velocity distribution and average flow velocity thereof in addition to the flow velocity distribution and average flow velocity in the present embodiment. According to FIG. 12, in the present embodiment, a decrease in the flow velocity appears in the vicinity of the discharge surface position P2 of the anode electrode 20b, but the flow velocity approaches an ideal value as it approaches the discharge surface position P1 of the cathode electrode 20a.

### 2.3 Effect

According to the present embodiment, since the symmetry between the cathode-side stagnation and the anode-side stagnation is improved and the flow velocity distribution of the laser gas passing through the discharge space 27 approaches the ideal flow velocity distribution, removing of the discharge product is improved. As a result, arc discharge is suppressed, and burst output without missing is possible as shown in FIG. 13.

### 3. Second Embodiment

### 3.1 Configuration

The gas laser device 2 according to a second embodiment of the present disclosure has a configuration similar to that of the gas laser device 2 according to the first embodiment except that the configuration in the laser chamber 10 is different.

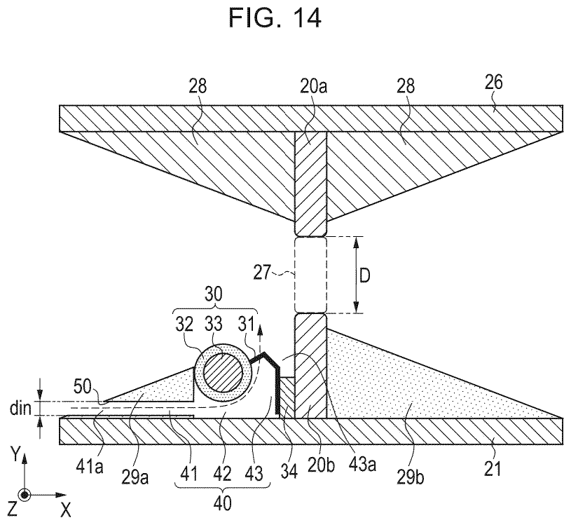

FIG. 14 shows in detail the configuration of the vicinity of the main electrode 20 in the laser chamber 10 according to the second embodiment. The present embodiment differs from the first embodiment only in the configuration of the conductive guide 29. In the present embodiment, the first guide member 29a of the conductive guide 29 is arranged close to the dielectric pipe 32. Further, the first guide member 29a is formed with a through hole 50 extending from the upstream end portion toward the anode electrode 20b along the X direction.

In the present embodiment, the first path 41 of the branched flow path 40 is configured by the through hole 50. The inlet port 41a into which the branched flow flows is an upstream opening of the through hole 50. The second path 42 is a gap between the dielectric pipe 32 and the ground plate 21 as in the first embodiment. The third path 43 is a gap between the dielectric pipe 32 and the anode electrode 20b as in the first embodiment. Here, the holding member 34 and a part of the preionization outer electrode 31 are present in the third path 43.

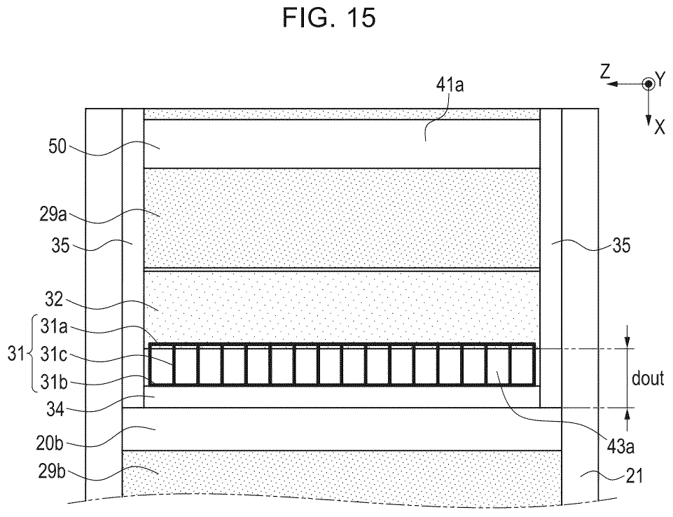

FIG. 15 is a plan view of a part including the anode electrode 20b and the dielectric pipe 32 viewed from the discharge space 27. The through hole 50 extends in the Z direction. Further, in the present embodiment, the pair of holding members 35 extend from the dielectric pipe 32 to the first guide member 29a. Thus, the pair of holding members 35 form both end surfaces of the first path 41 in the Z direction.

In the present embodiment as well, it is preferable to satisfy the relationship of dout≥din and the relationship of 0.1D≤din≤0.5D. Here, in the present embodiment, since the branched flow flows into the inlet port 41a in the X direction, the minimum width din is the length thereof in the Y direction.

### 3.2 Operation

The operation of the gas laser device 2 according to the present embodiment is similar to that of the first embodiment except for the difference due to the different configuration of the branched flow path 40.

FIG. 16 shows an example of a simulation result of the flow of the laser gas in the second embodiment. As shown in FIG. 16, even in the case in which the through hole 50 is the first path 41, the branched flow similar to that in the first embodiment occurs, so that a similar effect as in the first embodiment can be obtained.

### 3.3 Effect

According to the present embodiment, similarly to the first embodiment, since the symmetry between the cathode-side stagnation and the anode-side stagnation is improved and the flow velocity distribution of the laser gas passing through the discharge space 27 approaches the ideal flow velocity distribution as in the first embodiment, removing of the discharge product is improved. As a result, arc discharge is suppressed, and burst output without missing is possible.

### 4. Electronic Device Manufacturing Method

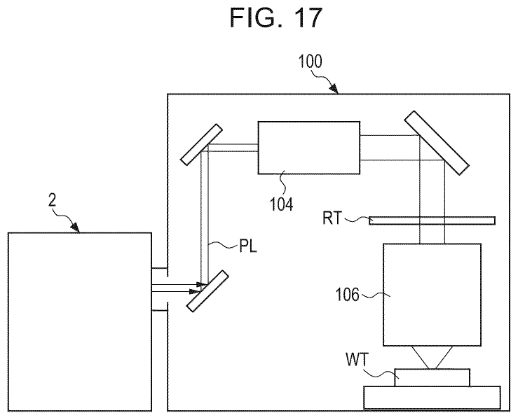

FIG. 17 schematically shows a configuration example of the exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the gas laser device 2. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

Here, not limited to the manufacturing of an electronic device, the gas laser device 2 may be used for laser processing such as drilling.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device for discharging and exciting a laser gas passing through a discharge space between a first discharge electrode and a second discharge electrode, comprising:
a plate supporting the first discharge electrode;
a guide member arranged on the plate and configured to guide the laser gas to the discharge space;
a dielectric pipe arranged between the guide member and the first discharge electrode as being spaced apart from each of the plate and the first discharge electrode;
a first path configured as including the guide member, and causing a part of the laser gas to flow therein as a branched flow;
a second path configured as including the dielectric pipe and the plate, and causing the branched flow flowing out from the first path to flow therethrough; and
a third path configured as including the dielectric pipe and the first discharge electrode, and guiding the branched flow flowing out from the second path to upstream of the laser gas with respect to the discharge space.

2. The gas laser device according to claim 1,
wherein the guide member is arranged as being spaced apart from the dielectric pipe, and
the first path is configured as including the guide member and the dielectric pipe.

3. The gas laser device according to claim 2,
wherein the dielectric pipe partially protrudes from an imaginary surface obtained by extending a surface of the guide member toward the discharge space.

4. The gas laser device according to claim 3,
a relationship of 0<dtop≤0.5F is satisfied, where dtop is a protrusion amount of the dielectric pipe and F is an outer diameter of the dielectric pipe.

5. The gas laser device according to claim 1,
wherein a through hole is formed in the guide member, and
the first path in configured by the through hole.

6. The gas laser device according to claim 1,
wherein a relationship of dout≥din is satisfied, where din is a minimum width of an inlet port of the first path in a direction perpendicular to a flowing direction of the branched flow, and dout is a minimum width of an outlet port of the third path in a direction perpendicular to a flowing direction of the branched flow.

7. The gas laser device according to claim 6,
wherein a relationship of 0.1D≤din≤0.5D is satisfied, where D is a distance between a discharge surface of the first discharge electrode and a discharge surface of the second discharge electrode.

8. The gas laser device according to claim 1,
wherein the first discharge electrode is an anode electrode, and
the second discharge electrode is a cathode electrode.

9. The gas laser device according to claim 8, further comprising a ladder-shaped preionization outer electrode arranged between the first discharge electrode and the dielectric pipe.

10. The gas laser device according to claim 9, further comprising a preionization inner electrode arranged in the dielectric pipe.

11. The gas laser device according to claim 10,
wherein the plate is a ground plate, and
the guide member has conductivity.

12. The gas laser device according to claim 11, further comprising a conductive guide including the guide member as a first guide member,
wherein the conductive guide includes a second guide member arranged downstream of the first discharge electrode on the plate to cover a side surface of the first discharge electrode.

13. The gas laser device according to claim 12,
wherein the first discharge electrode protrudes from a surface of the conductive guide toward the second discharge electrode.

14. The gas laser device according to claim 13, further comprising an insulating guide arranged to cover upstream and downstream side surfaces of the second discharge electrode.

15. The gas laser device according to claim 14,
wherein the second discharge electrode protrudes from a surface of the insulating guide toward the first discharge electrode.

16. An electronic device manufacturing method, comprising:
generating laser light using a gas laser device;
outputting the laser light to an exposure apparatus; and
exposing a photosensitive substrate to the laser light in the exposure apparatus to manufacture an electronic device,
the gas laser device being a gas laser device for discharging and exciting a laser gas passing through a discharge space between a first discharge electrode and a second discharge electrode and including:
a plate supporting the first discharge electrode;
a guide member arranged on the plate and configured to guide the laser gas to the discharge space;
a dielectric pipe arranged between the guide member and the first discharge electrode as being spaced apart from each of the plate and the first discharge electrode;
a first path configured as including the guide member, and causing a part of the laser gas to flow therein as a branched flow;
a second path configured as including the dielectric pipe and the plate, and causing the branched flow flowing out from the first path to flow therethrough; and
a third path configured as including the dielectric pipe and the first discharge electrode, and guiding the branched flow flowing out from the second path to upstream of the laser gas with respect to the discharge space.
